(19) United States
(12) Patent Application Publication
(10) Pub. No.: US 2006/0081903 A1
(43) Pub. Date: Apr. 20, 2006

(54) Semiconductor device and method of fabricating the same

(75) Inventors: Tomoki Inoue, Hyogo-ken (JP); Satoshi Aida, Hyogo-ken (JP); Yasushi Takahashi, Hyogo-ken (JP); Hitoshi Kobayashi, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/249,265

(22) Filed: Oct. 14, 2005

(30) Foreign Application Priority Data
Oct. 18, 2004 (JP) 2004-303442

(51) Int. Cl. H01L 29/94

(52) U.S. Cl. 257/304

(57) ABSTRACT

An n channel type power MOS field effect transistor has silica particles buried in a bottom portion of a trench and a gate electrode buried in another portion of the trench. The gate electrode is in contact with the silica particles. A gap of the silica particles is not filled with the gate electrode.

### CROSS REFERENCE TO RELATED APPLICATION

This application is based upon and claims the benefit of Priority from the prior Japanese Patent Application No. 2004-303442, filed on Oct. 18, 2004, the entire contents of which are incorporated herein by reference.

### FIELD OF THE INVENTION

The present invention relates to a semiconductor device and a method of fabricating the semiconductor device. More particularly, the semiconductor device includes such as a trench power MOS field effect transistor, a trench IGBT (Insulated Gate Bipolar Transistor), and has a trench structure.

### BACKGROUND OF THE DRAWINGS

In recent years, an STI (Shallow Trench Isolation) has been used in various LSIs, such as memory devices, logical circuits and the like, and isolates devices so as to permit high integration and high speed. A trench gate is formed in a power MOS field effect transistor and an IGBT so as to reduce on-state resistance, and to improve switching characteristics.

A silicon dioxide layer formed in the STI, is buried by such as a plasma CVD method (chemical Vapor Deposition method) or a TEOS (TetraEthyl Ortho Silicate) CVD method. A gate dielectric film, a gate electrode of a trench power MOS field effect transistor and a trench IGBT is buried in a silicon substrate. For example, the gate dielectric film is formed by thermally oxidizing a side portion and a bottom portion of the trench, the gate electrode is formed by burying a high concentration polysilicon film on the side portion and the bottom portion of the trench. The gate electrode is in contact with the gate dielectric film. This type semiconductor device is disclosed in U.S. Pat. No. 6,806,195 B1, and “Power Semiconductor Device and Power IC Handbook” CORONA PUBLISHING CO, LTD. filed on Jul. 30, 1996.

In this type semiconductor device, a stress appears in edges of the bottom of the trench by heat treatment in a selective oxidation method and a device formation process, the stress is induced by a difference of the thermal expansion coefficient between silicon and silicon dioxide. Crystal defects such as dislocations and stacking faults in a silicon substrate are caused by the stress. Due to the stress, a leak current of the device increases and a breakdown voltage of the device decreases.

Further, the crystal defects are more induced by a thermally oxidized film of the bottom portion of the trench when the thermally oxidized film is formed more thickly than other portions, so as to reduce a feedback capacitance having an influence on switching characteristics of the power MOS field effect transistor and the IGBT. For example, due to the crystal defects, a short circuit occurs between a source electrode and a drain electrode in the power MOS field effect transistor.

### SUMMARY OF THE INVENTION

According to an aspect of the invention is to provide a semiconductor device comprising a semiconductor substrate including a first layer of a first conductivity type, a second layer of a second conductivity type formed in a surface region of the first layer, a third layer of a first conductivity type selectively formed in a surface region of the second layer, a trench having a bottom surface and a side surface, and having a depth extending from a top surface of the third layer into the first layer, a gate dielectric film formed on the bottom surface and the side surface, dielectric particles buried in a bottom portion of the trench, and being in contact with the gate dielectric film, a gate electrode buried in another portion of the trench, being in contact with the gate dielectric film and the dielectric particles, and extending from a level of the top surface of the third layer to a boundary between the gate electrode and the dielectric particles, and extending beyond a level of boundary between the first layer and the second layer.

According to another aspect of the invention is to provide a method of fabricating a semiconductor device comprising forming a first semiconductor layer of a first conductivity type in a semiconductor substrate, forming a second semiconductor layer of a second conductivity type selectively in a surface region of the first semiconductor layer, forming a trench having a bottom surface and a side surface, and a depth extending from a top surface of the second layer into semiconductor substrate, forming a gate dielectric film formed on the bottom surface and the side surface of the trench, applying a solution of dielectric particles on the gate dielectric film and filling the trench with the solution, removing an excess portion of the dielectric particles so that remaining portions of the dielectric particles in a bottom portion of the trench, are positioned under a level of boundary between the first semiconductor layer and the semiconductor substrate, filling the trench with a material of a gate electrode on the buried dielectric particles.

### BRIEF DESCRIPTION OF THE DRAWINGS

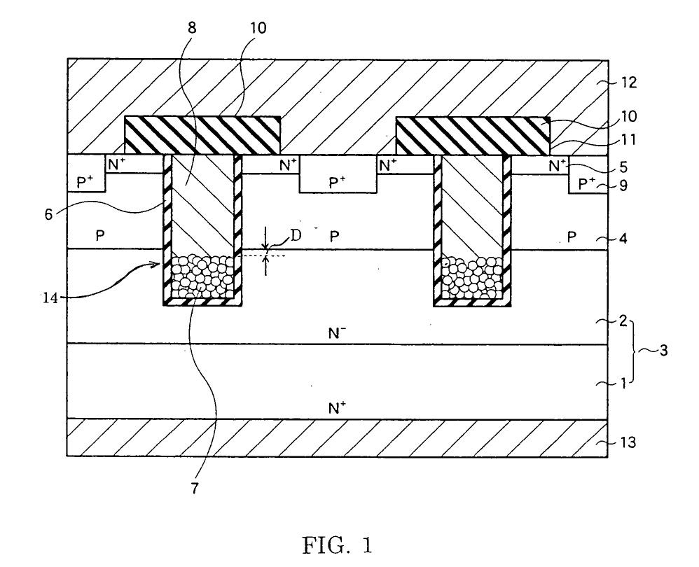

FIG. 1 is a cross-sectional view of a first embodiment of an n channel type trench power MOS field effect transistor according to the present invention.

FIG. 2 to 5 are cross-sectional views of a first embodiment of an n channel type trench power MOS field effect transistor fabricated according to a first embodiment of a method of fabricating an n channel type trench power MOS field effect transistor in accordance with the present invention.

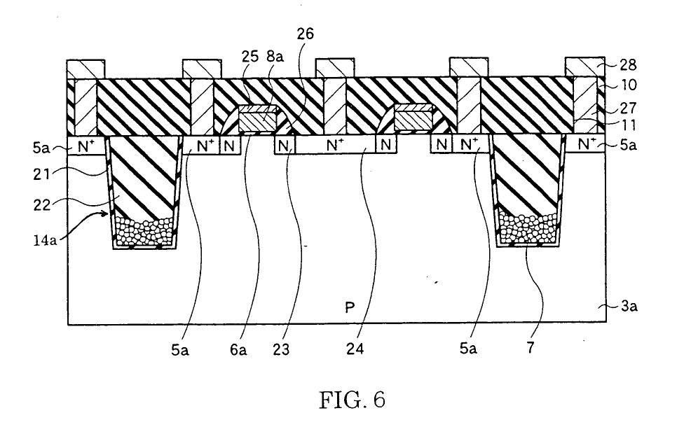

FIG. 6 is a cross-sectional view of a second embodiment of an n channel type trench power MOS field effect transistor according to the present invention.

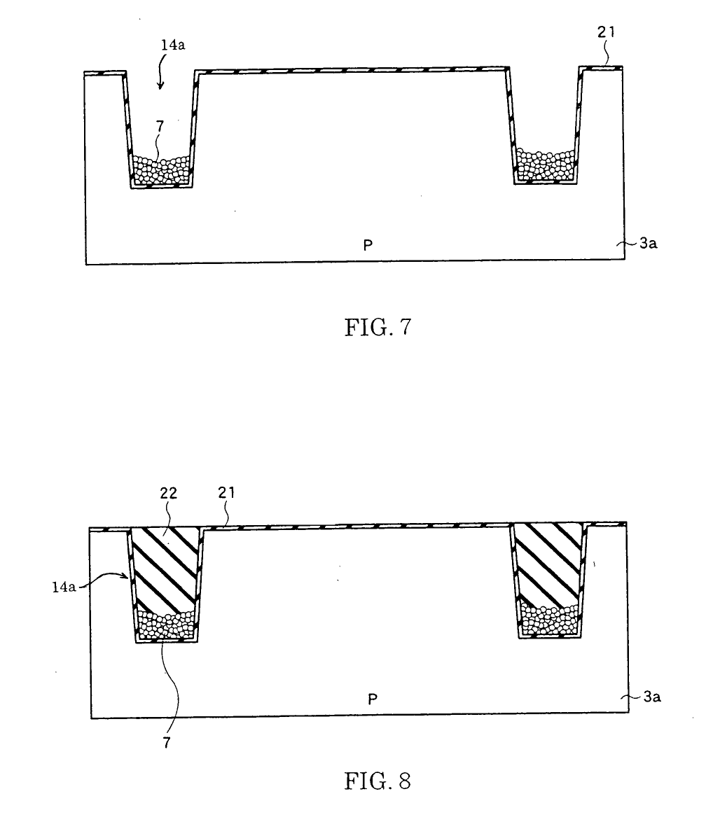

FIGS. 7 and 8 are cross-sectional views of a second embodiment of an n channel type trench power MOS field effect transistor fabricated according to a second embodiment of a method of fabricating an n channel type trench power MOS field effect transistor in accordance with the present invention.

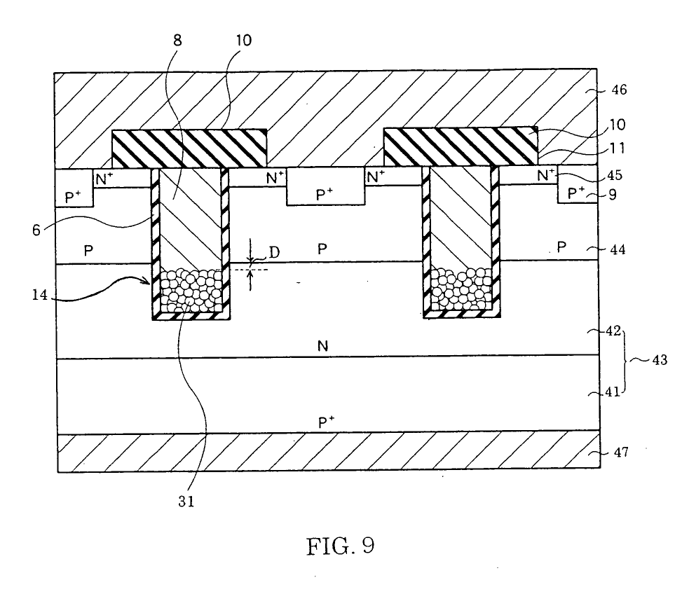

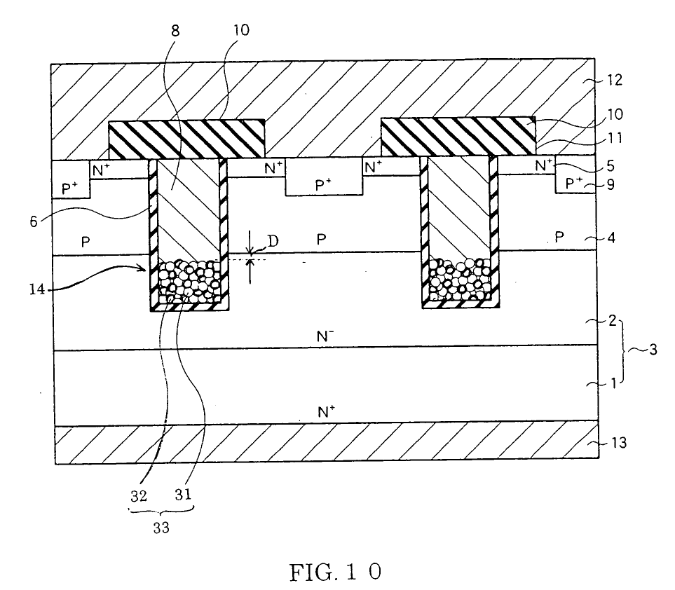

FIG. 9 is a cross-sectional view of a third embodiment of an IGBT according to the present invention.

FIG. 10 is a cross-sectional view of a fourth embodiment of an n channel type trench power MOS field effect transistor according to the present invention.

### DETAILED DESCRIPTION OF THE INVENTION

Embodiments of the present invention will be described below in detail with reference to the drawings.

With reference to FIG. 1, an n channel type trench power MOS field effect transistor as a semiconductor device of a first embodiment according to the invention is hereinafter explained. FIG. 1 is a cross-sectional view of the n channel type trench power MOS field effect transistor. The first embodiment involves the n channel type power MOS field effect transistor having a trench gate electrode.

In FIG. 1, the n channel type trench power MOS field effect transistor includes silicon substrate 3 as a drain region which is formed n type layer 2 on n⁺ type layer 1. P type layer 4 is selectively formed in n⁻ type layer 2. P⁺ type layer 9 is selectively formed in p type layer 4. N⁺ type source region 5 is selectively formed in p type layer 4, and is in contact with p⁺ type layer 9. N⁺ type source region 5 is formed shallower than p⁺ type layer 9.

Trench 14 includes a bottom surface and a side surface, and has a depth extending from a top surface of n⁺ type source region 5 into n⁻ type layer 2. Gate dielectric film 6 is formed on the bottom surface and the side surface. Silica particles 7 are buried in a bottom portion of trench 14, and are in contact with gate dielectric film 6. Gate electrode 8 is buried in another portion of trench 14, and is in contact with gate dielectric film 6 and silica particles 7, and extends from a level of the top surface of n⁺ type source region 5 to a boundary between gate electrode 8 and silica particles 7, and extends beyond a level of boundary between n⁻ type layer 2 and p type layer 4. A gap of silica particles 7 is filled with air. Air relaxes a stress induced in a silicon substrate by heat treatment.

In this embodiment, silica particles 7 are highly refined, and have a uniform particle diameter. A dielectric constant of silica particles 7 is 3.8, for example, and a dielectric constant of air is 1.0. A capacitance between a gate electrode and a drain electrode of the n channel type trench power MOS field effect transistor having silica particles 7 buried in a bottom portion of trench 14 may be reduced more than a capacitance between a gate electrode and a drain electrode of an n channel type power MOS field effect transistor having a silicon dioxide film buried in bottom portion of a trench.

Dielectric film 10 is formed over Gate electrode 8. Contact hole 11 is formed so as to expose p⁺ type layer 9 and a partial portion of n⁺ type source region 5 being in contact with p⁺ type layer 9. Source electrode 12 is formed on an exposed p⁺ type layer 9 and an exposed n⁺ type source region 5. Drain electrode 13 is formed on a back portion of n⁺ type layer 1. A side portion of p type layer 4 is a channel region of the n channel type trench power MOS field effect transistor. A side portion of gate electrode 8 being in contact with gate dielectric film 6, extends beyond a level of boundary between n⁻ type layer 2 and p type layer 4. A distance D illustrated between the boundary and the side portion of gate electrode 8 may be over 0 micron (D≧0). The n channel type trench power MOS field effect transistor don't turn on when the distance D is below 0 micron.

A method of fabricating a semiconductor device will be hereinafter explained with reference to FIG. 2 to 5. FIG. 2 to 5 are cross-sectional views of the n channel type trench power MOS field effect transistor according to the method.

As shown by FIG. 2, p type layer 4 is formed in silicon substrate 3 including n⁻ type layer 2 formed on n⁺ type layer 1. P type layer 4 is a backgate electrode, n⁺ type layer 1 and n⁻ type layer 2 as a silicon substrate are a drain region. Actually, p type layer 4 is selectively formed in silicon substrate 3 (not illustrated in FIG. 2). N⁻ type layer 2 is formed by epitaxial growth. P type layer 4 is formed by a ion implantation method and elevated temperature heat treatment, and may be also formed by epitaxial growth in the embodiment. N⁺ type source region 5 is selectively formed in p type layer 4 by a ion implantation method and elevated temperature heat treatment.

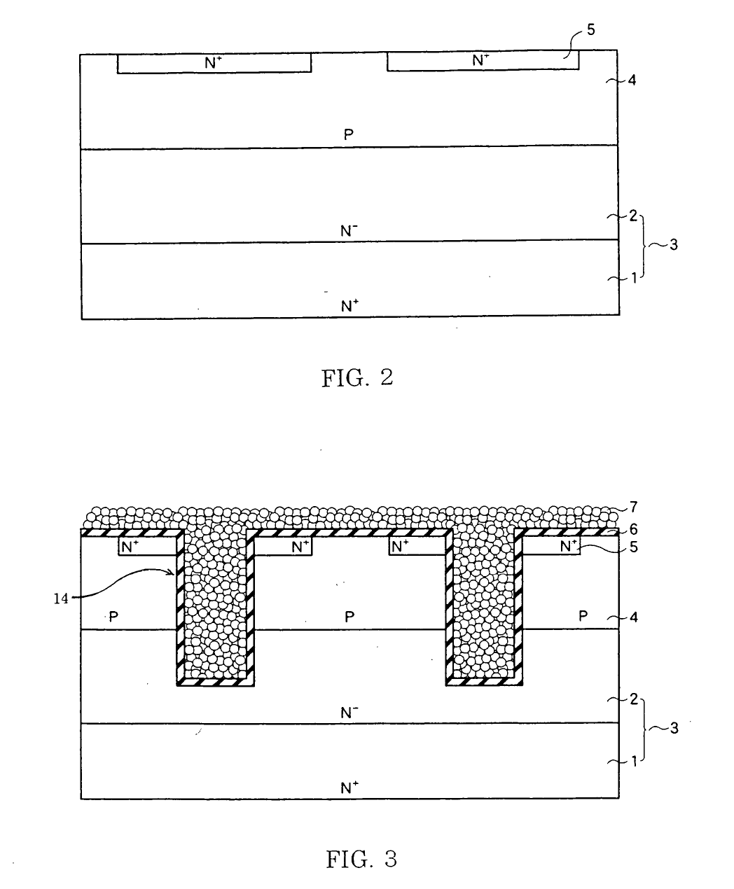

As shown by FIG. 3, a center portion of n⁺ type source region 5, p type layer 4, and a surface portion is selectively etched by an RIE (Reactive Ion Etching) method using chlorine based gas, for example, under existence of photo resist as a mask. A trench having a depth extending from a top surface of n⁺ type source region 5 into n⁻ type layer 2. A depth of the trench has 1 μm, and a width of the trench has 0.4 μm, for example.

After removing a damaged layer in silicon substrate 3 caused by an RIE using a wet etching process, for example, gate dielectric film 6 having a silicon oxide film is formed by elevated temperature oxidation. Laminate films including a silicon oxide film and a silicon nitride film may be applied to gate dielectric film 6 in the embodiment.

A solution dissolved silica particles 7 is applied on gate dielectric film 6 using a spin coat process, for example, and trench 14 is filled with the solution. Silica particles 7 are also named a colloidal silica, are formed by a liquid-phase process such as a metal alkoxide method or a micelle method, may be simple dispersed, may be highly refined, and may has a uniform particle diameter. A particle diameter of silica particles 7 may be larger than 0.004 μm (one hundredth of a width of trench 14), and may be smaller than 0.04 μm (one tenth of a width of trench 14) so as to uniformly bury silica particles 7 in a bottom portion of trench 14.

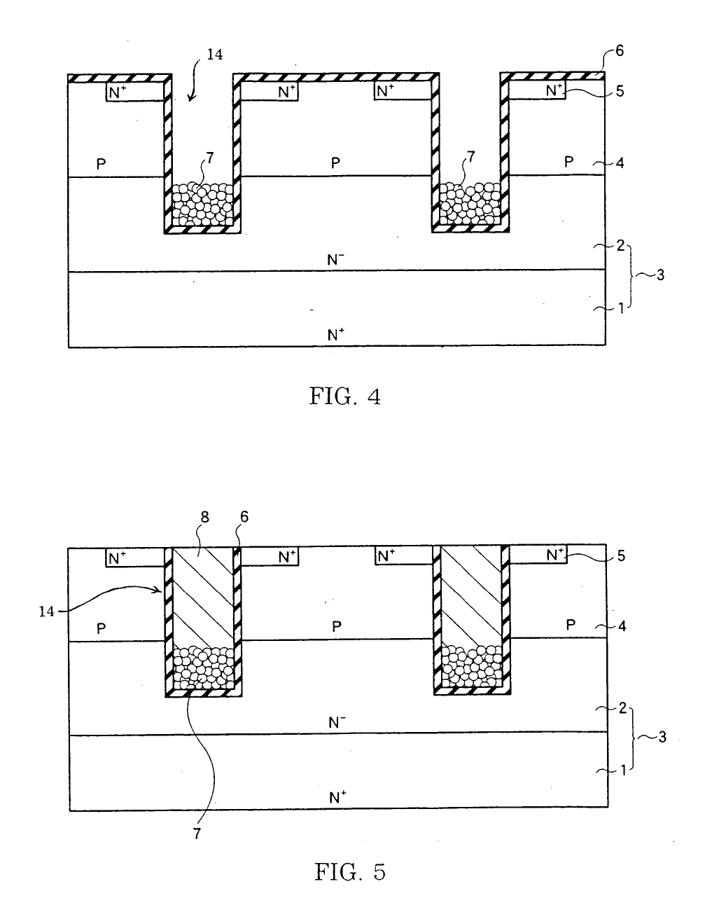

As shown by FIG. 4, excess silica particles 7 formed on a surface portion of gate dielectric film 6 and in a surface portion of trench 14, are removed by a CMP (Chemical Mechanical Polishing) method, for example, and silica particles 7 are saved in a bottom portion of trench 14 under a level of boundary between p type layer 4 and n⁻ type layer 2, and are in contact with gate dielectric film 6. Saved silica particles 7 are nonuniformly left in trench 14 when a particle diameter of silica particles 7 is larger than 0.04 μm (one tenth of a width of trench 14), silica particles 7 may not be uniformly buried in a bottom portion of trench 14. On the other hand, silica particles 7 are flied out during the CMP operation when a particle diameter of silica particles 7 is smaller than 0.004 μm (one hundredth of a width of trench 14), silica particles 7 may not be uniformly buried in a bottom portion of trench 14. A brush scrubbing process rotating a brush and supplying water may be also used in the embodiment. Minute quantities of hydrofluoric acid (HF) may be added in this case. Gate dielectric film 6 may be reoxidized when hydrofluoric acid is used. A particle diameter of silica particles 7 is measured by such as a TEM (Transmission Electron Microscopy) or a SEM (Scanning Electron Microscopy). Solvent leaving in trench 14 is volatilized by elevated temperature heat treatment. Silica particles 7 and gate dielectric film 6 are fastened.

As shown by FIG. 5, an n⁺ type polysilicon film as gate electrode 8 is deposited on silica particles 7 and silicon substrate 3 by a CVD method. A particle diameter of silica particles 7 is smaller than a grain size of the n⁺ type polysilicon film, a gap of silica particles 7 is not filled with the n⁺ polysilicon film. Excess n⁺ type polysilicon film and gate dielectric film 6 on a surface portion of silicon substrate 3 are removed by a CMP method, for example, and a surface portion of p type layer 4 and n⁺ type source region 5 are exposed. An impurity saved on a surface portion of silicon substrate 3 is removed by an aftertreatment, and the surface portion of silicon substrate 3 is cleaned up. Gate dielectric film 6 on a surface portion of silicon substrate 3 may not be removed in the embodiment.

After this step, p⁺ type layer 9 being in contact with n⁺ type source region 5 is formed. Dielectric film 10 is deposited over the entire face of silicon substrate 3. Contact holes are opened in the dielectric film 10. Metal wirings are formed. The n channel type trench power MOS field effect transistor is completed as shown in FIG. 1.

The semiconductor device in accordance with the above embodiment is the n channel type trench power MOS field effect transistor. The n channel type trench power MOS field effect transistor has silica particles 7 buried in a bottom portion of trench 14 and gate electrode 8 buried in other portions of trench 14. Gate electrode 8 is in contact with silica particles 7. A gap of silica particles 7 is not filled with gate electrode 8. A stress induced in a bottom portion of trench 14 by heat treatment such as a selective oxidation method, an STI method and a device formation process may be reduced more than a stress induced in a bottom portion of a trench having not dielectric particles. The stress is caused by a difference of the thermal expansion coefficient between a silicon and a silicon dioxide. Crystal defects such as dislocations and stacking faults in a silicon substrate are caused by the stress. The crystal defects may be reduced. Leak current of the semiconductor device may be reduced, and breakdown voltage of the semiconductor device may be maintained more than a conventional semiconductor device.

Further, silica particles 7 as a insulator are buried in a bottom portion of trench 14, and air having a value of relative dielectric constant smaller than that of silica particles 7 is filled with a gap of silica particles 7. Therefore, a capacitance between a gate electrode and a drain electrode in the n channel type trench power MOS field effect transistor may be reduced, and a feedback capacitance may be reduced. Switching characteristics of the n channel type trench power MOS field effect transistor may be improved more than that of a conventional n channel type power MOS field effect transistor.

In the above embodiment, silica particles 7 are formed by a spin coat process in a trench and on gate dielectric film 6. Silica particles 7 may be also formed by a CVD method. A trench structure having silica particles 7 buried under a gate electrode is applied to the n channel type trench power MOS field effect transistor. A trench structure having silica particles 7 buried under a gate electrode may be also applied to a p channel type trench power MOS field effect transistor.

An n channel type MOS field effect transistor as a semiconductor device of a second embodiment according to the invention is hereinafter explained with reference to FIG. 6. FIG. 6 is a cross-sectional view of the n channel type MOS field effect transistor. With respect to each portion of the second embodiment, the same portion of the first embodiment shown FIG. 1 is designed by the same reference numeral. The second embodiment involves the n channel type MOS field effect transistor having an STI.

As shown by FIG. 6, the n channel type MOS field effect transistor includes p type silicon substrate 3a. N⁺ type source region 5a, n type layer 23, and n⁺ type drain region 24 are selectively formed in p type silicon substrate 3a, respectively. N type layer 23 is in contact with n⁺ type source region 5a and n⁺ type drain region 24, respectively.

Sallow trench 14a having a bottom surface and a side surface is formed in p type silicon substrate 3a. Shallow trench 14a is in contact with n⁺ type source region 5a. Silicon oxide film 21 is formed on the bottom surface and the side surface. Silica particles 7 are buried in a bottom portion of shallow trench 14a, and are in contact with silicon oxide film 21. Silicon dioxide layer 22 is buried in another shallow trench 14a, and is in contact with silicon oxide film 21 and silica particles 7. Other dielectric layer instead of silicon dioxide layer 22 may be also formed in the embodiment. A gap of silica particles 7 is filled with air. A stress induced in p type silicon substrate 3a by elevated temperature heat treatment is reduced by air.

Laminate films consisting of a gate dielectric film 6a, gate electrode 8a and gate electrode passivation film 25 are selectively formed on p type silicon substrate 3a. N type layer 23 is selectively formed in p type silicon substrate 3a, under existence of the laminate films as a mask. Side wall dielectric film 26 is selectively formed on p type silicon substrate 3a and is in contact with a side portion of the laminate films. N⁺ type source region 5a and n⁺ type drain region 24 is selectively formed in p type silicon substrate 3a, under existence of side wall dielectric film 26 as a mask.

Dielectric film 10 is formed over gate electrode 8a and gate electrode passivation film 25. Contact hole 11 is formed so as to expose a partial portion of n⁺ type source region 5a and n⁺ type drain region 24. Via metal 27 is formed on exposed n⁺ type source region 5a and exposed n⁺ type drain region 24. Metal wiring 28 is selectively formed on via metal 27. Silica particles 7 formed in a bottom portion of shallow trench 14a may be formed under a level of boundary between n⁺ type source region 5a and p type silicon substrate 3a.

A method of fabricating a semiconductor device will be hereinafter explained with reference to FIGS. 7 and 8. FIGS. 7 and 8 are cross-sectional views of the n channel type MOS field effect transistor according to the method.

As shown by FIG. 7, shallow trench 14a including a bottom surface and a side surface is selectively formed by an RIE method under existence of photo resist as a mask, for example, in p type silicon substrate 3a. In this embodiment, A depth of shallow trench 14a has 0.3 μm, and a width of shallow trench 14a has 0.15 μm, for example. After removing a damaged layer in silicon substrate 3a caused by an RIE, silicon oxide film 21 is formed by elevated temperature oxidation.

A solution dissolved silica particles 7 is applied on silicon oxide film 21 using a spin coat process, for example. A particle diameter of silica particles 7 may be larger than 0.0015 μm (one hundredth of a width of trench 14a), may be smaller than 0.015 μm (one tenth of a width of trench 14) so as to uniformly bury in a bottom portion of shallow trench 14a.

Excess silica particles 7 formed on a surface portion of silicon oxide film 21 and in a surface portion of shallow trench 14a, are removed by a CMP method, and silica particles 7 are saved in a bottom portion of shallow trench 14a, and are in contact with silicon oxide film 21. Saved silica particles 7 are nonuniformly left in shallow trench 14a when a particle diameter of silica particles 7 is larger than 0.015 μm (one tenth of a width of shallow trench 14a), silica particles 7 may not be uniformly buried in a bottom portion of shallow trench 14a. On the other hand, silica particles 7 are flied out during the CMP operation when a particle diameter of silica particles 7 is smaller than 0.0015 μm (one hundredth of a width of shallow trench 14a), silica particles 7 may not be uniformly buried in a bottom portion of shallow trench 14a.

As shown by FIG. 8, silicon dioxide layer 22 is deposited on silica particles 7 and silicon substrate 3a by a CVD method. A particle diameter of silica particles 7 is smaller than a particle size of silicon dioxide layer 22, a gap of silica particles 7 is not filled with silicon dioxide layer 22. Excess silicon dioxide layer 22 on a surface portion of silicon substrate 3a, are removed by a CMP process, and a surface portion of silicon oxide film 21 are exposed. Shallow trench 14a (STI) is completed as shown in FIG. 8.

After this step, a gate dielectric film, a gate electrode, a source and drain region, interlayer insulating film, contact holes, metal wirings, and the like are successively formed. The n channel type MOS field effect transistor is completed as shown in FIG. 6.

The semiconductor device in accordance with the above embodiment is the n channel type MOS field effect transistor. The n channel type MOS field effect transistor has silica particles 7 buried in a bottom portion of shallow trench 14a and silicon dioxide layer 22 buried in another portion of shallow trench 14a. Silicon dioxide layer 22 is in contact with silica particles 7. A gap of silica particles 7 is not filled with silicon dioxide layer 22. A stress induced in a bottom portion of shallow trench 14a by heat treatment such as a selective oxidation method, an STI method and a device formation process may be reduced more than a stress induced in a bottom portion of shallow trench having not dielectric particles. The stress is caused by a difference of the thermal expansion coefficient between a silicon and a silicon dioxide. Crystal defects such as dislocations and stacking faults in a silicon substrate are caused by the stress. The crystal-defects may be reduced. Leak current of the semiconductor device may be reduced, and breakdown voltage of the semiconductor device may be maintained more than a conventional semiconductor device.

An IGBT (Insulated Gate Bipolar Transistor) as the semiconductor device of a third embodiment according to the invention is hereinafter explained with reference to FIG. 9. FIG. 9 is a cross-sectional view of the IGBT. With respect to each portion of the third embodiment, the same portion of the first embodiment shown FIG. 1 is designed by the same reference numeral.

As shown by FIG. 9, the IGBT includes silicon substrate 43 which is formed n type base layer 42 on p⁺ type emitter layer 41. P type base layer 44 is selectively formed in n type base layer 42. P⁺ type layer 9 is selectively formed in p type base layer 44. N⁺ type emitter region 45 is selectively formed in p type layer 4 shallower than p⁺ type layer 9, and is in contact with p⁺ type layer 9.

Trench 14 includes a bottom surface and a side surface, and has a depth extending from a top surface of n⁺ type emitter region 45 into n type base layer 42. Gate dielectric film 6 is formed on the bottom surface and the side surface. Alumina particles 31 are buried in a bottom portion of trench 14, and are in contact with gate dielectric film 6. Gate electrode 8 is buried in another portion of trench 14, and is in contact with gate dielectric film 6 and alumina particles 31, and extends from a level of the top surface of n⁺ type emitter region 45 to a boundary between gate electrode 8 and alumina particles 31, and extends beyond a level of boundary between n type base layer 42 and p type base layer 44. A gap of alumina particles 31 is filled with air. Air relaxes a stress induced in a silicon substrate by heat treatment. A distance D illustrated between the boundary (between n type base layer 42 and p type base layer 44) and the side portion of gate electrode 8 may be over 0 micron (D≧0).

In this embodiment, alumina particles 31 may be highly refined, and have a uniform particle diameter. A dielectric constant of alumina particles 31 is 8.5, for example, and a dielectric constant of air is 1.0. A capacitance between n type base layer 42 and a gate electrode of the IGBT may be reduced more than a capacitance between n type base layer 42 and a gate electrode of an IGBT having a alumina film (Al₂O₃) buried in whole portion of a trench.

Dielectric film 10 is formed over gate electrode 8. Contact hole 11 is formed so as to expose p⁺ type layer 9 and a partial portion of n⁺ type emitter region 45 being in contact with p⁺ type layer 9. A emitter electrode 46 is formed on an exposed p⁺ type layer 9 and an exposed n⁺ type emitter region 45. Collector electrode 47 is formed on a back portion of p⁺ type emitter layer 41.

The semiconductor device in accordance with the above embodiment is the IGBT. The IGBT has alumina particles 31 buried in a bottom portion of trench 14 and gate electrode 8 buried in another portion of trench 14, being in contact with alumina particles 31. A gap of alumina particles 31 is not filled with gate electrode 8. A stress induced in a bottom portion of trench 14 by heat treatment such as a selective oxidation method, an STI method and a device formation process may be reduced more than a stress induced in a bottom portion of trench having not dielectric particles. The stress is caused by a difference of the thermal expansion coefficient between a silicon and a silicon dioxide. Crystal defects such as dislocations and stacking faults in a silicon substrate are caused by the stress. The crystal defects may be reduced. Leak current of the semiconductor device may be reduced, and breakdown voltage of the semiconductor device may be maintained more than a conventional semiconductor device (IGBT).

An n channel type trench power MOS field effect transistor as a semiconductor device of a fourth embodiment according to the invention is hereinafter explained with reference to FIG. 10. FIG. 10 is a cross-sectional view of the n channel type trench power MOS field effect transistor. With respect to each portion of the fourth embodiment, the same portion of the first embodiment shown FIG. 1 is designed by the same reference numeral.

As shown by FIG. 10, the n channel type trench power MOS field effect transistor includes silicon substrate 3 as a drain region which is formed n⁻ type layer 2 on a n⁺ type layer 1. P type layer 4 is selectively formed in n⁻ type layer 2. P⁺ type layer 9 is selectively formed in p type layer 4. N⁺ type source region 5 is selectively formed in p type layer 4, and is in contact with p⁺ type layer 9. N⁺ type source region 5 is formed shallower than p⁺ type layer 9.

Trench 14 includes a bottom surface and a side surface, and has a depth extending from a top surface of n⁺ type source region 5 into n⁻ type layer 2. Gate dielectric film 6 is formed on the bottom surface and the side surface. Compound particles 33 consisting of alumina particles 31 and SiC particle 32 are buried in a bottom portion of trench 14, and are in contact with gate dielectric film 6. Gate electrode 8 is buried in another portion of trench 14, and is in contact with gate dielectric film 6 and compound particles 33, and extends from a level of the top surface of n⁺ type source region 5 to a boundary between gate electrode 8 and compound particles 33, and extends beyond a level of boundary between n⁻ type layer 2 and p type layer 4. A gap of compound particles 33 is filled with air. Air relaxes a stress induced in a silicon substrate by heat treatment. A side portion of gate electrode 8 being in contact with gate dielectric film 6, extends beyond a level of boundary between n type layer 2 and p type layer 4. A distance D illustrated between the boundary and the side portion of gate electrode 8 may be over 0 micron (D≧0). The n channel type trench power MOS field effect transistor don't turn on when the distance D is below 0 micron.

In this embodiment, alumina particles 31 and SiC particle 32 may be highly refined, and have a uniform particle diameter. Two varieties of dielectric particles such as silica particles and alumina particles, for example, may be applied in the embodiment. Compound particles including three varieties of dielectric particles, may be also applied in the embodiment.

A dielectric film 10 is formed over gate electrode 8. Contact hole 11 is formed so as to expose p⁺ type layer 9 and a partial portion of n⁺ type source region 5 being in contact with p⁺ type layer 9. Source electrode 12 is formed on exposed p⁺ type layer 9 and exposed n⁺ type source region 5. Drain electrode 13 is formed on a back portion of n⁺ type layer 1.

The semiconductor device in accordance with the above embodiment is the n channel type trench power MOS field effect transistor. The n channel type trench power MOS field effect transistor has compound particles 33 consisting of alumina particles 31 and SiC particle 32 buried in a bottom portion of trench 14 and gate electrode 8 buried in another portion of trench 14. Gate electrode is in contact with compound particles 33. A gap of compound particles 33 is not filled with gate electrode 8. A stress induced in a bottom portion of trench 14 by heat treatment such as a selective oxidation method, an STI method, and a device formation process may be reduced more than a stress induced in a bottom portion of trench having not dielectric particles. The stress is caused by a difference of the thermal expansion coefficient between a silicon and a silicon dioxide. Crystal defects such as dislocations and stacking faults in a silicon substrate are caused by the stress. The crystal defects may be reduced. Leak current of the semiconductor device may be reduced, and breakdown voltage of the semiconductor device may be maintained more than a conventional semiconductor device.

Additional advantages and modifications will readily occur those skilled in the art. Therefore, the present invention in its broader aspects is not limited to the specific details and representative embodiments shown and described herein.

What is claimed is:

1. A semiconductor device, comprising:
a semiconductor substrate including a first layer of a first conductivity type;
a second layer of a second conductivity type formed in a surface region of the first layer;
a third layer of a first conductivity type selectively formed in a surface region of the second layer;
a trench having a bottom surface and a side surface, and having a depth extending from a top surface of the third layer into the first layer;
a gate dielectric film formed on the bottom surface and the side surface
dielectric particles buried in a bottom portion of the trench, and being in contact with the gate dielectric film; and
a gate electrode buried in another portion of the trench, being in contact with the gate dielectric film and the dielectric particles, and extending from a level of the top surface of the third layer to a boundary between the gate electrode and the dielectric particles, and extending beyond a level of boundary between the first layer and the second layer.

2. A semiconductor device according to claim 1, wherein the semiconductor substrate further comprises a forth layer of a second conductivity type formed on a back region of the first layer.

3. A semiconductor device according to claim 1, further comprising a fifth layer of a second conductivity type formed in the second layer in which the third layer is not being formed.

4. A semiconductor device according to claim 1, wherein the semiconductor device is a power MOS field effect transistor, the dielectric particles are silica.

5. A semiconductor device according to claim 1, wherein a particle diameter of the dielectric particles is larger than one hundredth of a width of the trench, and is smaller than one tenth of the width of the trench.

6. A semiconductor device according to claim 1, wherein the dielectric particles include at least one alumina and silica.

7. A semiconductor device according to claim 1, wherein the dielectric particles include composite particles of more than two species.

8. A semiconductor device according to claim 1, wherein a gap of the dielectric particles is filled with air.

9. A semiconductor device, comprising:
a semiconductor substrate of a first conductivity type;
a trench having a bottom surface and a side surface;
a dielectric film formed on the bottom surface and the side surface;
dielectric particles buried in a bottom portion of the trench, and being in contact with the dielectric film; and
a dielectric layer buried in another portion of the trench, being in contact with the dielectric film and the dielectric particles, and extending from a level of the top surface of the semiconductor substrate.

10. A semiconductor device according to claim 9, further comprising a source region and a drain region of a second conductivity type formed in the surface region of the semiconductor substrate, and being in contact with a side portion of the dielectric film.

11. A semiconductor device according to claim 9, wherein a particle diameter of the dielectric particles is larger than one hundredth of a width of the trench, and is smaller than one tenth of the width of the trench.

12. A semiconductor device according to claim 9, wherein the dielectric particles include at least one alumina and silica.

13. A semiconductor device according to claim 9, wherein the dielectric particles include composite particles of more than two species.

14. A semiconductor device according to claim 9, wherein a gap of the dielectric particles is filled with air.

15. A method of fabricating a semiconductor device, comprising:
forming a first semiconductor layer of a first conductivity type in a semiconductor substrate;
forming a second semiconductor layer of a second conductivity type selectively in a surface region of the first semiconductor layer;
forming a trench having a bottom surface and a side surface, and a depth extending from a top surface of the second layer into the semiconductor substrate;
forming a gate dielectric film formed on the bottom surface and the side surface of the trench;
applying a solution of dielectric particles on the gate dielectric film and filling the trench with the solution;
removing an excess portion of the dielectric particles so that remaining portions of the dielectric particles in a bottom portion of the trench, are positioned under a level of boundary between the first semiconductor layer and the semiconductor substrate; and
filling the trench with a material of a gate electrode on the buried dielectric particles.

16. A method according to claim 15, wherein the semiconductor device is a power MOS field effect transistor, the dielectric particles are silica.

17. A method according to claim 15, further comprising:
fastening the dielectric particles and the gate dielectric film using an elevated temperature treatment after burying the dielectric particles in the bottom of the trench.

18. A method according to claim 15, wherein the step of burying the dielectric particles in the bottom of the trench is carried out using a chemical mechanical polishing method.

19. A method according to claim 15, wherein the step of burying the dielectric particles in the bottom of the trench is carried out using a brush scrubbing process rotating a brush and supplying water.

20. A method according to claim 15, wherein the step of burying the dielectric particles in the bottom of the trench is carried out using a brush scrubbing process rotating a brush and supplying water added minute quantities of hydrofluoric acid.
